(19) United States
(12) Patent Application Publication
(10) Pub. No.: US 2025/0106647 A1
(43) Pub. Date: Mar. 27, 2025

(54) DETERMINING SIMULATION INFORMATION FOR A NETWORK TWIN

(71) Applicant: Lenovo (Singapore) Pte. Ltd., New Tech Park (SG)

(72) Inventors: Emmanouil Pateromichelakis, Viersen (DE); Dimitrios Karampatsis, Ruislip (GB)

(21) Appl. No.: 18/730,608

(22) PCT Filed: Mar. 11, 2022
(86) PCT No.: PCT/EP2022/056368

§ 371 Date: Jul. 19, 2024

(30) Foreign Application Priority Data
Jan. 21, 2022 (GR) 20220100054

(51) Int. Cl. H04W 16/22; H04W 24/06

(52) U.S. Cl. CPC H04W 16/22; H04W 24/06

(57) ABSTRACT

Apparatuses, methods, and systems are disclosed for determining simulation information for a network twin. One method includes receiving, at a configuration entity, a request for data corresponding to an event from a consumer. The request includes a request for the data to be derived based on use of a digital twin. The method includes creating a network twin construct based on the request, an application service, and a type of the consumer. The network twin construct includes a digital twin instance. The method includes configuring a simulation environment at the wireless communication system. The simulation environment includes the network twin construct. The method includes determining at least one simulation parameter at the simulation environment for the network twin construct based on the request received from the consumer.

### FIELD

The subject matter disclosed herein relates generally to wireless communications and more particularly relates to determining simulation information for a network twin.

### BACKGROUND

In certain wireless communications networks, digital twins may be used. In such networks, processing and/or complexity may be increased by using digital twins.

### BRIEF SUMMARY

Methods for determining simulation information for a network twin are disclosed. Apparatuses and systems also perform the functions of the methods. One embodiment of a method includes receiving, at a configuration entity, a request for data corresponding to an event from a consumer. The request indicates a request for the data to be derived based on use of at least one digital twin of at least one network entity of a wireless communication system. In some embodiments, the method includes creating a network twin construct based on the request, an application service, and a type of the consumer. The network twin construct includes at least one digital twin instance of the at least one network entity of the wireless communication system. In certain embodiments, the method includes configuring a simulation environment at the wireless communication system. The simulation environment includes the network twin construct. In various embodiments, the method includes determining at least one simulation parameter at the simulation environment for the network twin construct based on the request received from the consumer.

One apparatus for determining simulation information for a network twin includes a configuration entity. In some embodiments, the apparatus includes a receiver that receives a request for data corresponding to an event from a consumer. The request indicates a request for the data to be derived based on use of at least one digital twin of at least one network entity of a wireless communication system. In various embodiments, the apparatus includes a processor that: creates a network twin construct based on the request, an application service, and a type of the consumer, wherein the network twin construct comprises at least one digital twin instance of the at least one network entity of the wireless communication system; configures a simulation environment at the wireless communication system, wherein the simulation environment includes the network twin construct; and determines at least one simulation parameter at the simulation environment for the network twin construct based on the request received from the consumer.

Another embodiment of a method for determining simulation information for a network twin includes receiving, at a network twin construct, at least one simulation parameter. In some embodiments, the method includes deriving simulations at a simulation environment for combining hypothetical communication parameters based on the at least one simulation parameter, an application service, and a type of a consumer. The simulations produce data. In certain embodiments, the method includes transmitting the data to the consumer. The consumer includes a network function, an application function, or a combination thereof.

Another apparatus for determining simulation information for a network twin includes a network twin construct. In some embodiments, the apparatus includes a receiver that receives at least one simulation parameter. In various embodiments, the apparatus includes a processor that derives simulations at a simulation environment for combining hypothetical communication parameters based on the at least one simulation parameter, an application service, and a type of a consumer. The simulations produce data. In certain embodiments, the apparatus includes a transmitter that transmits the data to the consumer. The consumer includes a network function, an application function, or a combination thereof.

A further embodiment of a method for determining simulation information for a network twin includes receiving, at a network analytics function, a request from an application function for a digital twin enabled data analytics event. In some embodiments, the method includes associating the digital twin enabled data analytics event with an application service profile. In certain embodiments, the method includes requesting data from a network entity. The simulation data is requested to be derived based on use of network twins at a wireless communication system. In various embodiments, the method includes receiving the data from the network entity.

A further apparatus for determining simulation information for a network twin includes a network analytics function. In some embodiments, the apparatus includes a receiver that receives a request from an application function for a digital twin enabled data analytics event. In various embodiments, the apparatus includes a processor that associates the digital twin enabled data analytics event with an application service profile. In certain embodiments, the apparatus includes a transmitter that requests data from a network entity. The simulation data is requested to be derived based on use of network twins at a wireless communication system. The receiver receives the data from the network entity.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a schematic block diagram illustrating one embodiment of a wireless communication system for determining simulation information for a network twin;

FIG. 2 is a schematic block diagram illustrating one embodiment of an apparatus that may be used for determining simulation information for a network twin;

FIG. 3 is a schematic block diagram illustrating one embodiment of an apparatus that may be used for determining simulation information for a network twin;

FIG. 4 is a schematic block diagram illustrating one embodiment of a system in a configuration phase;

FIG. 5 is a schematic block diagram illustrating one embodiment of a system in a network twin operation phase;

FIG. 6 is a schematic block diagram illustrating one embodiment of a system that uses twining for analytics enhancements;

FIG. 7 is a schematic block diagram illustrating one embodiment of a system for RAN twining;

FIG. 8 is a schematic block diagram illustrating one embodiment of a system with a split of DT and PT;

FIG. 9 is a schematic block diagram illustrating one embodiment of an O-RAN system;

FIG. 10 is a schematic block diagram illustrating one embodiment of a system implementing the third embodiment;

FIG. 11 is a flow chart diagram illustrating one embodiment of a method for determining simulation information for a network twin;

FIG. 12 is a flow chart diagram illustrating another embodiment of a method for determining simulation information for a network twin; and

FIG. 13 is a flow chart diagram illustrating a further embodiment of a method for determining simulation information for a network twin.

### DETAILED DESCRIPTION

As will be appreciated by one skilled in the art, aspects of the embodiments may be embodied as a system, apparatus, method, or program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a program product embodied in one or more computer readable storage devices storing machine readable code, computer readable code, and/or program code, referred hereafter as code. The storage devices may be tangible, non-transitory, and/or non-transmission. The storage devices may not embody signals. In a certain embodiment, the storage devices only employ signals for accessing code.

Certain of the functional units described in this specification may be labeled as modules, in order to more particularly emphasize their implementation independence. For example, a module may be implemented as a hardware circuit comprising custom very-large-scale integration (“VLSI”) circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in code and/or software for execution by various types of processors. An identified module of code may, for instance, include one or more physical or logical blocks of executable code which may, for instance, be organized as an object, procedure, or function. Nevertheless, the executables of an identified module need not be physically located together, but may include disparate instructions stored in different locations which, when joined logically together, include the module and achieve the stated purpose for the module.

Indeed, a module of code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different computer readable storage devices. Where a module or portions of a module are implemented in software, the software portions are stored on one or more computer readable storage devices.

Any combination of one or more computer readable medium may be utilized. The computer readable medium may be a computer readable storage medium. The computer readable storage medium may be a storage device storing the code. The storage device may be, for example, but not limited to, an electronic, magnetic, optical, electromagnetic, infrared, holographic, micromechanical, or semiconductor system, apparatus, or device, or any suitable combination of the foregoing.

More specific examples (a non-exhaustive list) of the storage device would include the following: an electrical connection having one or more wires, a portable computer diskette, a hard disk, a random access memory (“RAM”), a read-only memory (“ROM”), an erasable programmable read-only memory (“EPROM” or Flash memory), a portable compact disc read-only memory (“CD-ROM”), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Code for carrying out operations for embodiments may be any number of lines and may be written in any combination of one or more programming languages including an object oriented programming language such as Python, Ruby, Java, Smalltalk, C++, or the like, and conventional procedural programming languages, such as the “C” programming language, or the like, and/or machine languages such as assembly languages. The code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider).

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and program products according to embodiments. It will be understood that each block of the schematic flowchart diagrams and/or schematic block diagrams, and combinations of blocks in the schematic flowchart diagrams and/or schematic block diagrams, can be implemented by code. The code may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The code may also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams and/or schematic block diagrams block or blocks.

The code may also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and program products according to various embodiments. In this regard, each block in the schematic flowchart diagrams and/or schematic block diagrams may represent a module, segment, or portion of code, which includes one or more executable instructions of the code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

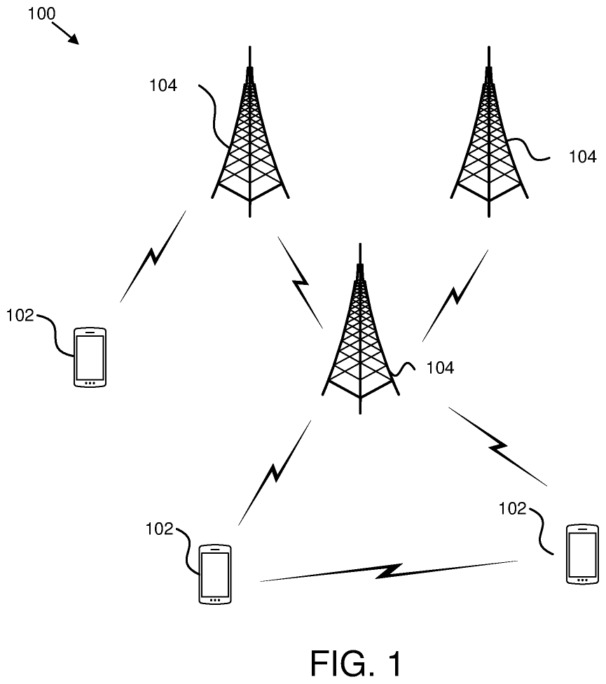

FIG. 1 depicts an embodiment of a wireless communication system 100 for determining simulation information for a network twin. As used herein, a network twin may be a digital twin representation of a 5GC, a slice, a single NF, a RAN node, backhaul transport, a UE modem, network protocol, an AF, and so forth. Moreover, a network twin may refer to a digital twin of at least one entity of a wireless communication system. In one embodiment, the wireless communication system 100 includes remote units 102 and network units 104. Even though a specific number of remote units 102 and network units 104 are depicted in FIG. 1, one of skill in the art will recognize that any number of remote units 102 and network units 104 may be included in the wireless communication system 100. It should be noted that the wireless communication system 100 includes the interfaces among any combination of remote units 102 and network units 104.

In one embodiment, the remote units 102 may include computing devices, such as desktop computers, laptop computers, personal digital assistants (“PDAs”), tablet computers, smart phones, smart televisions (e.g., televisions connected to the Internet), set-top boxes, game consoles, security systems (including security cameras), vehicle on-board computers, network devices (e.g., routers, switches, modems), aerial vehicles, drones, or the like. In some embodiments, the remote units 102 include wearable devices, such as smart watches, fitness bands, optical head-mounted displays, or the like. Moreover, the remote units 102 may be referred to as subscriber units, mobiles, mobile stations, users, terminals, mobile terminals, fixed terminals, subscriber stations, UE, user terminals, a device, or by other terminology used in the art. The remote units 102 may communicate directly with one or more of the network units 104 via UL communication signals. In certain embodiments, the remote units 102 may communicate directly with other remote units 102 via sidelink communication.

The network units 104 may be distributed over a geographic region. In certain embodiments, a network unit 104 may also be referred to and/or may include one or more of an access point, an access terminal, a base, a base station, a location server, a core network (“CN”), a radio network entity, a Node-B, an evolved node-B (“eNB”), a 5G node-B (“gNB”), a Home Node-B, a relay node, a device, a core network, an aerial server, a radio access node, an access point (“AP”), new radio (“NR”), a network entity, an access and mobility management function (“AMF”), a unified data management (“UDM”), a unified data repository (“UDR”), a UDM/UDR, a policy control function (“PCF”), a radio access network (“RAN”), a network slice selection function (“NSSF”), an operations, administration, and management (“OAM”), a session management function (“SMF”), a user plane function (“UPF”), an application function, an authentication server function (“AUSF”), security anchor functionality (“SEAF”), trusted non-3GPP gateway function (“TNGF”), an application function, a service enabler architecture layer (“SEAL”) function, a vertical application enabler server, an edge enabler server, an edge configuration server, a mobile edge computing platform function, a mobile edge computing application, a middleware entity, a network slice capability management server, or by any other terminology used in the art. The network units 104 are generally part of a radio access network that includes one or more controllers communicably coupled to one or more corresponding network units 104. The radio access network is generally communicably coupled to one or more core networks, which may be coupled to other networks, like the Internet and public switched telephone networks, among other networks. These and other elements of radio access and core networks are not illustrated but are well known generally by those having ordinary skill in the art.

In one implementation, the wireless communication system 100 is compliant with NR protocols standardized in third generation partnership project (“3GPP”), wherein the network unit 104 transmits using an OFDM modulation scheme on the downlink (“DL”) and the remote units 102 transmit on the uplink (“UL”) using a single-carrier frequency division multiple access (“SC-FDMA”) scheme or an orthogonal frequency division multiplexing (“OFDM”) scheme. More generally, however, the wireless communication system 100 may implement some other open or proprietary communication protocol, for example, WiMAX, institute of electrical and electronics engineers (“IEEE”) 802.11 variants, global system for mobile communications (“GSM”), general packet radio service (“GPRS”), universal mobile telecommunications system (“UMTS”), long term evolution (“LTE”) variants, code division multiple access 2000 (“CDMA2000”), Bluetooth®, ZigBee, Sigfoxx, among other protocols. The present disclosure is not intended to be limited to the implementation of any particular wireless communication system architecture or protocol.

The network units 104 may serve a number of remote units 102 within a serving area, for example, a cell or a cell sector via a wireless communication link. The network units 104 transmit DL communication signals to serve the remote units 102 in the time, frequency, and/or spatial domain.

In various embodiments, a network unit 104 may receive, at a configuration entity, a request for data corresponding to an event from a consumer. The request indicates a request for the data to be derived based on use of at least one digital twin of at least one network entity of a wireless communication system. In some embodiments, the network unit 104 may create a network twin construct based on the request, an application service, and a type of the consumer.

The network twin construct includes at least one digital twin instance of the at least one network entity of the wireless communication system. In certain embodiments, the network unit 104 may configure a simulation environment at the wireless communication system. The simulation environment includes the network twin construct. In various embodiments, the network unit 104 may determine at least one simulation parameter at the simulation environment for the network twin construct based on the request received from the consumer. Accordingly, the network unit 104 may be used for determining simulation information for a network twin.

In certain embodiments, a network unit 104 may receive, at a network twin construct, at least one simulation parameter. In some embodiments, the network unit 104 may derive simulations at a simulation environment for combining hypothetical communication parameters based on the at least one simulation parameter, an application service, and a type of a consumer. The simulations produce data. In certain embodiments, the network unit 104 may transmit the data to the consumer. The consumer includes a network function, an application function, or a combination thereof. Accordingly, the network unit 104 may be used for determining simulation information for a network twin.

In some embodiments, a network unit 104 may receive, at a network analytics function, a request from an application function for a digital twin enabled data analytics event. In some embodiments, the network unit 104 may associate the digital twin enabled data analytics event with an application service profile. In certain embodiments, the network unit 104 may request data from a network entity. The simulation data is requested to be derived based on use of network twins at a wireless communication system. In various embodiments, the network unit 104 may receive the data from the network entity. Accordingly, the network unit 104 may be used for determining simulation information for a network twin.

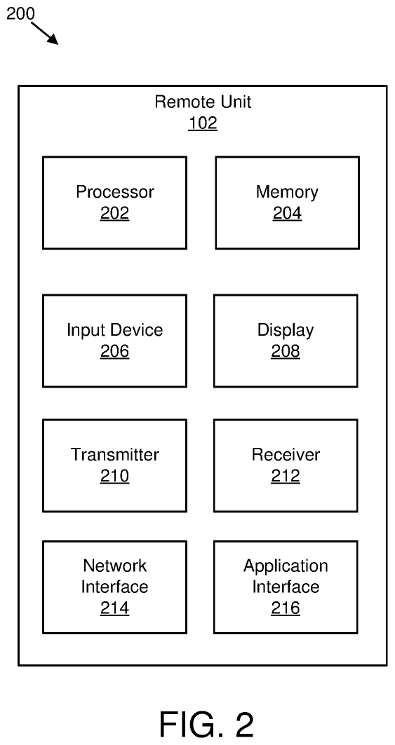

FIG. 2 depicts one embodiment of an apparatus 200 that may be used for determining simulation information for a network twin. The apparatus 200 includes one embodiment of the remote unit 102. Furthermore, the remote unit 102 may include a processor 202, a memory 204, an input device 206, a display 208, a transmitter 210, a receiver 212, a network interface 214, and an application interface 216. In some embodiments, the input device 206 and the display 208 are combined into a single device, such as a touchscreen. In certain embodiments, the remote unit 102 may not include any input device 206 and/or display 208. In various embodiments, the remote unit 102 may include one or more of the processor 202, the memory 204, the transmitter 210, and the receiver 212, and may not include the input device 206 and/or the display 208.

The processor 202, in one embodiment, may include any known controller capable of executing computer-readable instructions and/or capable of performing logical operations. For example, the processor 202 may be a microcontroller, a microprocessor, a central processing unit (“CPU”), a graphics processing unit (“GPU”), an auxiliary processing unit, a field programmable gate array (“FPGA”), or similar programmable controller. In some embodiments, the processor 202 executes instructions stored in the memory 204 to perform the methods and routines described herein. The processor 202 is communicatively coupled to the memory 204, the input device 206, the display 208, the transmitter 210, and the receiver 212.

The memory 204, in one embodiment, is a computer readable storage medium. In some embodiments, the memory 204 includes volatile computer storage media. For example, the memory 204 may include a RAM, including dynamic RAM (“DRAM”), synchronous dynamic RAM (“SDRAM”), and/or static RAM (“SRAM”). In some embodiments, the memory 204 includes non-volatile computer storage media. For example, the memory 204 may include a hard disk drive, a flash memory, or any other suitable non-volatile computer storage device. In some embodiments, the memory 204 includes both volatile and non-volatile computer storage media. In some embodiments, the memory 204 also stores program code and related data, such as an operating system or other controller algorithms operating on the remote unit 102.

The input device 206, in one embodiment, may include any known computer input device including a touch panel, a button, a keyboard, a stylus, a microphone, or the like. In some embodiments, the input device 206 may be integrated with the display 208, for example, as a touchscreen or similar touch-sensitive display. In some embodiments, the input device 206 includes a touchscreen such that text may be input using a virtual keyboard displayed on the touchscreen and/or by handwriting on the touchscreen. In some embodiments, the input device 206 includes two or more different devices, such as a keyboard and a touch panel.

The display 208, in one embodiment, may include any known electronically controllable display or display device. The display 208 may be designed to output visual, audible, and/or haptic signals. In some embodiments, the display 208 includes an electronic display capable of outputting visual data to a user. For example, the display 208 may include, but is not limited to, a liquid crystal display (“LCD”), a light emitting diode (“LED”) display, an organic light emitting diode (“OLED”) display, a projector, or similar display device capable of outputting images, text, or the like to a user. As another, non-limiting, example, the display 208 may include a wearable display such as a smart watch, smart glasses, a heads-up display, or the like. Further, the display 208 may be a component of a smart phone, a personal digital assistant, a television, a table computer, a notebook (laptop) computer, a personal computer, a vehicle dashboard, or the like.

In certain embodiments, the display 208 includes one or more speakers for producing sound. For example, the display 208 may produce an audible alert or notification (e.g., a beep or chime). In some embodiments, the display 208 includes one or more haptic devices for producing vibrations, motion, or other haptic feedback. In some embodiments, all or portions of the display 208 may be integrated with the input device 206. For example, the input device 206 and display 208 may form a touchscreen or similar touch-sensitive display. In other embodiments, the display 208 may be located near the input device 206.

Although only one transmitter 210 and one receiver 212 are illustrated, the remote unit 102 may have any suitable number of transmitters 210 and receivers 212. The transmitter 210 and the receiver 212 may be any suitable type of transmitters and receivers. In one embodiment, the transmitter 210 and the receiver 212 may be part of a transceiver. The network interface 214 (or network interfaces) may support 3GPP reference points, such as Uu, N1, PC5, etc. Other network interfaces may also be supported as understood by one of ordinary skill in the art. The application interface 216 (or application interfaces) may support 3GPP defined APIs.

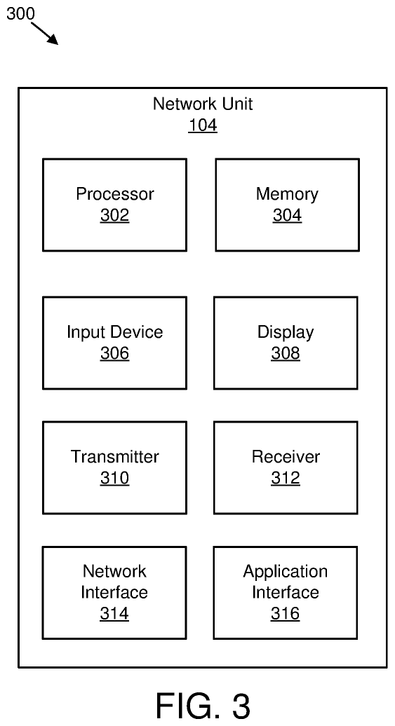

FIG. 3 depicts one embodiment of an apparatus 300 that may be used for determining simulation information for a network twin. The apparatus 300 includes one embodiment of the network unit 104. Furthermore, the network unit 104 may include a processor 302, a memory 304, an input device 306, a display 308, a transmitter 310, a receiver 312, a network interface 314, and an application interface 316. As may be appreciated, the processor 302, the memory 304, the input device 306, the display 308, the transmitter 310, the receiver 312, the network interface 314, and the application interface 316 may be substantially similar to the processor 202, the memory 204, the input device 206, the display 208, the transmitter 210, the receiver 212, the network interface 314, and the application interface 316 of the remote unit 102, respectively. The network interface 314 (or network interfaces) may support 3GPP reference points, such as Uu, N1, N2 and N3, N33, N5. Moreover, other network interfaces may be supported as understood by one of ordinary skill in the art. The application interface 316 (or application interfaces) may support 3GPP defined northbound APIs.

In certain embodiments, the receiver 312 receives a request for data corresponding to an event from a consumer. The request indicates a request for the data to be derived based on use of at least one digital twin of at least one network entity of a wireless communication system. In various embodiments, the processor 302: creates a network twin construct based on the request, an application service, and a type of the consumer, wherein the network twin construct comprises at least one digital twin instance of the at least one network entity of the wireless communication system; configures a simulation environment at the wireless communication system, wherein the simulation environment includes the network twin construct; and determines at least one simulation parameter at the simulation environment for the network twin construct based on the request received from the consumer.

In some embodiments, the receiver 312 receives at least one simulation parameter. In various embodiments, the processor 302 derives simulations at a simulation environment for combining hypothetical communication parameters based on the at least one simulation parameter, an application service, and a type of a consumer. The simulations produce data. In certain embodiments, the transmitter 310 transmits the data to the consumer. The consumer includes a network function, an application function, or a combination thereof.

In various embodiments, the receiver 312 receives a request from an application function for a digital twin enabled data analytics event. In various embodiments, the processor 302 associates the digital twin enabled data analytics event with an application service profile. In certain embodiments, the transmitter 310 requests data from a network entity. The simulation data is requested to be derived based on use of network twins at a wireless communication system. The receiver receives the data from the network entity.

In certain embodiments, such as beyond 5G, a system may include multiple segments and a traditional network as a pipe may include commodity hardware and/or software. The system may include a radio access network (“RAN”), transport network (“TN”), core network (“CN”) and an edge cloud, cloud, and/or application enablement domains for an edge to edge (“E2E”) user plane (“UP”), whereas a control and management plane may be unified and may include virtualized services which may be deployed within access and core network domains and may be able to be exposed to a vertical customer to enable an end to end service to be optimized for subscribers.

In some embodiments, players involved in a system may be increased and stakeholders involved at developing and/or producing platform capabilities within an extended system may be increased and may span a vertical domain, an edge domain, a regional domain, a core cloud provider domain, an application programming interface (“API”), and/or software development kit (“SDK”) third party providers.

In various embodiments, extensions of a system may include a set of problems to be too, problems related to edge, cloud resource management, and/or control, selecting a best data network (“DN”) for an application, application portability, migration aspects, extension of slicing to cover edge and/or vertical cloud components, trusted application-to-application interactions, and so forth.

In certain embodiments, there may be a need for testing and verifying new services that span across different domains and for evaluating an impact on different part of the system. In some embodiments, pro-active monitoring of events related to different parts of a system (e.g., device, RAN, TN, CN, edge DN, DN, middleware) may help solve some issues; however, it may pose complexity to different stakeholders and may require a level of coordination and/or orchestration as well as negotiations between players involved. Furthermore, a vertical customer may need extensive testing before using 5G access for critical operations, and may require backup access networks to be available for critical services and/or redundancy.

In some embodiments, use of artificial intelligence (“AI”) and/or machine learning (“ML”) services may be essential to operate at a network system to automate procedures and allow for pro-active handling of failures and performance degradations within the system (e.g., which cannot be tolerated in critical and deterministic vertical services). The use of AI and/or ML services may be an opportunity for future cellular systems; however, it may pose significant challenges in terms of where and how the AI and/or ML model needs to be trained and how to deal at the network side with issues related to expected complexity and huge amount of processing and resource requirement for training ML models.

A vertical service may be defined as an application service provided by a vertical industry stakeholder. Moreover, the vertical service, may be a V2X service, a factory of the future (“FoF”) service, a UAS service, an eHealth service, an AR and/or VR service, a service deployed at a stadium event, and so forth. Moreover, a vertical device may be defined as a device running or consuming a vertical service. The vertical device may be an IoT device, a V2X UE, a FoF UE, a UAV or UAV controller, a smartphone running an eHealth application, and so forth.

In some scenarios and/or use cases characteristic for requiring further enhancements in terms of automation, testing, and verification may be classified in different categories: 1) use cases where a network twin may enable a third party and/or application function (“AF”) to receive notifications, recommendations, and/or predictions on service operation for one or more user equipments (“UEs”) based on analytics-driven simulations for hypothetical scenarios at the network twin; and/or 2) use cases where the network twin may enable shaping of a service level agreement (“SLA”) for new services and provisioning of service parameters for specific events (e.g., area-based or user-centric).

Various embodiments may correspond to automotive and/or vehicle to everything (“V2X”) verticals. V2X may be the key driver for fifth generation (“5G”) evolution since automated driving is evolving, may be able to ensure safe and comfortable driving, and may be connected within an automated driving zone. Automakers may need network coverage, technologies, and information from all involved physical parameters to ensure that key performance indicators (“KPIs”) may be fulfilled, and that a sufficient level of redundancy is present.

In certain embodiments, one aspect of testing of an expected performance may occur before going in a high automation mode with support of a cellular network. An automaker may need to make sure that it uses 5G and/or sixth generation (“6G”) as a main connectivity option. For such embodiments, testing may need to be provided either at a vertical premises or at a mobile network operator (“MNO”) and/or cloud provider to enable the access network to deliver in all possible worst-case scenarios considering all information from a target area where connected cars move.

In some embodiments, a vehicle driver may ask whether and when automated driving is possible before starting a journey or during the trip. In particular, the vehicle driver may ask for information from an MNO. The MNO may evaluate whether it is possible and may provide an estimation of when, whether, and what path to follow to have full automation along the path. The MNO may propose an alternative route where full automated driving can be achieved. In various embodiments, a V2X server may perform service provisioning for various traffic efficiency and safety services within a service area.

In certain embodiments, an MNO may be able to take into account all scenarios and different hypotheses for a trip. This may include predicted performance in different cells within a route, objects which may lead to performance fluctuations (e.g., due to non-line of sight (“NLOS”)), analytics per cell, slice, and/or UE predicted performance and real-time measurements along the path (e.g., which cannot be known in advance).

In some embodiments, there may be a stadium use case in which a stadium event is ready to start. The event service provider may provide some services and/or applications for fans (e.g., offer live 8K video from a pitch or a stage) with fans able to choose from multiple camera angles in real time, show data overlays and stats about players on audience's mobile or wearable devices, sell merchandise or additional services on the fly to customers using mobile devices, support pop-up retailers with secure wireless connections for payment processing, extend market reach by offering the same live video and information feeds to fans who couldn't get to the venue.

In various embodiments, a service provider and/or organizer asks a MNO to make a test and/or simulation on communications for services offered and/or whether a bandwidth is enough. This may cover different worst-case scenarios (e.g., a load of the stadium, unexpected events, different average use of services offered, and so forth) and possible network related resource and functional requirements. This may change the plans of the service provider to reduce the coverage of the service offering, downgrade requirements, or charge more for some services available for a limited number of people. An MNO may need to be able to take into account all what if scenarios and different hypotheses for a stadium event. This may include a predicted performance based on a mixture of services that may be offered and an expected demand and/or connection density. However, this may not be easy to be performed without previous preparation and the MNO may need to emulate an eHealth use case. eHealth applications may be key drivers for next generation systems since these may be life savers especially in remote areas (e.g., by intelligent monitoring of patient's conditions, remote surgeries, connected ambulances, and so forth).

In certain embodiments, an eHealth service provider (e.g., a hospital or a doctor) may proactively monitor a patent's conditions and ask an MNO to run what-if simulations and/or worst case scenarios for a potential critical health situation for a given area and/or route of a patient.

In some embodiments, a patient with known health issues (e.g., COVID, old, etc.) may subscribe to a service provider (“SP”) (e.g., hospital) for receiving remote health support at a home or at known locations (e.g., office), or at known routes (e.g., when moving to work, when moving to a supermarket, and so forth). The MNO may need to simulate all possible worst case scenarios if an event happens. For example, a possible worst case simulation may be for a case if a patient is feeling unwell and needs to perform an e-surgery while moving to an office, and all testing and/or simulations in an area, and may provide an estimation that the surgery will be >X % successful and what is required in terms of connectivity and performance for a given expect what-if scenario to increase chances for success of an operation. This may trigger a service provider to ask for more bandwidth and/or resources or different slices in a target area; and a service provider may charge an insurance and/or patient more for achieving a higher success rate of the surgery.

In various embodiments, there may be a slicing use case. In such embodiments, a private slice of an MNO may be instantiated for potential use at a small factory. A factory owner may not require a private slice 24/7 in all areas since there may be connectivity via other means. However, the factory owner may not know in what extend it will use a private slice and what exact requirements in terms of performance are needed. Also, a 3rd party factory SP may need to operate (e.g., original equipment manufacturers (“OEMs”) may update firmware for internet of things (“IoT”) sensors, a logistics company to track shipments, and so forth) and may require wireless connectivity. All these requirements may shape a SLA with an MNO, and a simple assumption may be to overprovision resources, but a factory owner may require to optimize a process to avoid unnecessary charges.

In certain embodiments, an MNO may receive requirements (e.g., including services to be deployed, when and/or where these operate and possible additional requirements and/or failures that may come up). In such embodiments, the MNO may need to perform a testing of an expected performance targeting certain applications and/or services and consider a target factory area, and so forth. The use of a network twin (e.g., virtualizes potential slice constituents and a factory area and runs simulations for given services and/or devices) may help taking all possible realistic “deviations” and “failures” into account and inform a factory owner on a granular network requirements that may shape a SLA and an agreement on an actual need and charging of a private slice.

In some embodiments, there may be a drone use case. In such embodiments, a drone flight may be expected (e.g., drone carrying multiple apps such as a camera and so forth). An unmanned aerial server (“UAS”) operator may request from an MNO an expected performance of an expected flight (e.g., target may be to reach point B, or to follow some way points) and what is the best route (e.g., network centric route) or network access configurations and/or slices to do that. So, the UAS may invoke an API for requesting a twin based prediction of a route, and the MNO, after performing what if simulations on possible fluctuations of quality of service (“QoS”) and their impact on service operation, may expose information on a predicted performance and a possible recommendation of an alternative route with optimal network performance and/or coverage.

In various embodiments, open radio access network (“O-RAN”) use cases. In O-RAN, there may be multiple use cases as possible scenarios where O-RAN and, in particular the AI-assisted network optimization, may be beneficial. There may be radio access network (“RAN”) optimization use cases (e.g., traffic steering: user-centric AI-enabled traffic steering to switching among air interfaces (e.g., sub-6 GHz, mmWave), predictive quality of experience (“QoE”) and/or QoS optimization, massive multiple-input multiple-output (“MIMO”) optimization). In certain embodiments, there may be use cases for verticals: 1) RAN slice assurance; 2) automotive industry and/or V2X (e.g., context based dynamic handover management for V2X); 3) use cases for unmanned aerial systems (“UAVs”), flight path based radio resource allocation for UAV applications; and/or 4) use cases for industrial IoT (“IIoT”).

In some embodiments, radio resource management (“RRM”) and/or self-organized network (“SON”) algorithms may operate at third party applications and aim to optimize a UE and RAN performance with the assistance of big data analytics for clusters of O-RAN cells. In such embodiments, these use cases may require real-time data and events from a RAN and/or UE, and may pose significant complexity to have all measurements to be provided to a RAN controller which servers numerous cells. One key challenge may be what happens if there are conflicts for requests that target the same resources. An open RAN intelligent controller (“RIC”) (“O-RIC”) may include a conflict mitigation module; however, there may be different possible conflicts (e.g., indirect) and a resolution may be a difficult task. In such embodiments, an O-RAN network twin may provide necessary testing and simulations covering all possible shortcomings tailored to a different use case.

In various embodiments, a current 5GS architecture may be enhanced to support end-to-end service provisioning (e.g., especially if considering segments that do not fall in an MNO domain and require a holistic view and understanding of an entire “system”). This may require extensive and sophisticated use case analysis and what-if scenario testing based on a customer's needs. This may increase the complexity of the system since it may require real time measurements and simulating different environments continuously to allow sufficient testing of an expected performance and capturing worst-case scenarios.

In certain embodiments: 1) network optimization may be based on hypothetical load and resource situation conditions; 2) 3GPP data analytics services may be made more intelligent to make real-time predictions without making them complex; 3) extensive testing of a network and/or UE performance may be performed for specific applications and/or verticals; 4) exposure to a third party customer's application of predictions of the system performance may be enabled under different hypothetical what-if scenarios; and/or 5) a 5G-native system level simulation tool may be derived and may be exposed as a service to meet different consumer requirements.

In some embodiments, a prediction within a 5G system (“5GS”) may be supported by a control plane, a management plane (e.g., OAM), and/or an application enablement layer (e.g., AF driven analytics). Data Analytics may be provided by different domains in 3GPP.

In various embodiments, use of analytics and/or statistics for optimizing RAN performance with the use of minimization of drive tests (“MDT”) and the use of a trace collection entity (“TCE”). In such embodiments, MDT enables operators to collect UE measurements together with location information (e.g., if available) with the purpose of optimizing network management while reducing operational effects and maintenance costs. Some use cases may be as follows: 1) coverage optimization: this function covers multiple objectives, such as coverage mapping, coverage hole detection, identification of weak coverage, detection of excessive interference, uplink coverage verification, and so forth; 2) mobility optimization: this function aims to optimize mobility performance by monitoring cells with a high handover rate and a provided coverage; 3) capacity optimization: this function aims to improve strategies of network planning and network capacity verification and/or optimization; and/or 4) QoS verification: this function is aimed to verify the service level that can be offered to users in different parts of a network.

In certain embodiments, management data analytics service (“MDAS”) may provide data analytics for a network. MDAS may be deployed at different levels (e.g., at a domain level (e.g., RAN, CN, network slice subnet) or in a centralized manner (e.g., in a public land mobile network (“PLMN”) level)). One objective of MDAS may be to optimize a management plane (e.g., in network and/or domain level, in slice and/or slice subnet level) by performing analytics based on network management data. Such service may be exposed to a third party and/or MDAS service consumer to provide performance measurement (“PM”) analytics, fault measurement (“FM”) Analytics, network slice instance (“NSI”) and/or network slice subnet instance (“NSSI”) analytics, and/or optionally recommend appropriate management actions (e.g., scaling of resources, admission control, load balancing of traffic, and so forth).

In some embodiments, a network data analytics function (“NWDAF”) may provide several analytics services which include UE and/or network performance: 1) observed service experience related network data analytics that may include: service experience for a UE, a group UEs, any UE in an application, or a set of applications over a specific UP path (e.g., user plane function (“UPF”), data network access identifier (“DNAI”) and edge configuration (“EC”) server)—the inputs may be from an AF, network functions (“NFs”), and an OAM-from UPF the inputs may include: QoS flow bit rate, QoS flow packet delay, # of packet transmissions (“TX”) and/or re-TX-from AF, the inputs may include: QoE metrics, service experience, app location; 2) UE communication analytics (e.g., NWDAF collects UE UL and/or DL data rate and traffic volume from UPF and N4 session level data); 3) user data congestion analytics: NWDAF gets from UPF or AF: UL and/or DL throughput and peak UL and/or DL throughput; 4) redundant transmission experience related analytics (e.g., UL and/or DL packet delay from UE to UPF); and/or 5) DN performance analytics (e.g., performance data from AF like average packet delay, average loss rate and throughput).

In various embodiments, an application data analytics enablement service (“ADAES”) may provide application data analytics services (e.g., stats and/or predictions) to optimize an application service operation by notifying an application specific layer, and potentially 5GS, for expected and/or predicted application service parameters changes considering both on-network and off-network deployments (e.g., related to application QoS parameters)

In certain embodiments, providing a real-time data to data analytics function may be a challenging task (e.g., high signaling and/or complexity) and due to a real-time nature of measurements (e.g., per transmission time interval (“TTI”)) this information may get outdated (e.g., to provide real time predictions).

In some embodiments, data may not be sufficient and a data analytics service may want to run simulations for what-if scenarios for deriving different sets of data per a worst case scenario. This may be very useful for vertical customers, since an MNO may guarantee a certain predictive performance based on extensive testing.

In various embodiments, there may be an O-RAN alliance. In certain embodiments, an O-RAN reference architecture may enable next generation RAN infrastructures. The architecture may be designed with principles of intelligence and openness, and the O-RAN architecture may be the foundation for building a virtualized RAN on open hardware with embedded AI-powered radio control that may be envisioned by operators around the globe.

In certain embodiments, an O-RAN reference architecture may provide next generation radio resource management (“RRM”) with embedded intelligence while optionally accommodating legacy RRM. This may reside within a RIC rear RT function layer. The RIC near-RT may be completely compatible with legacy RRM and its design may enhance operational challenging functions such as per-UE controlled load-balancing, resource block (“RB”) management, interference detection, and/or mitigation.

In some embodiments, in a RIC architecture, a shared data layer (“SDL”) may be a capability layer that includes a database functions as: 1) a UE-network information base (“UE-NIB”): UE-NIB maintains a list of UEs and associated data, UE-NIB also maintains tracking and correlation of UE identities associated with connected RAN nodes—xApps may provide UE related information to be stored in the UE-NIB database and to be used by AI and/or ML algorithms; and/or 2) RAN-network information base (“R-NIB”): the R-NIB stores the configurations and near real-time information relating to connected E2 nodes and the mappings between them—xApps may provide radio access network related information to be stored in the R-NIB database, and to be used by AI and/or ML algorithms.

In various embodiments, there may be a mechanism for configuring and operating a digital twin of one or more NFs for a given vertical application requirement to allow for extensive testing and identifying network requirements for a given application service. Such embodiments may include: 1) configuration of a network twin and twin constructs based on a use case and/or simulation environment; and/or 2) an AF and/or NF-triggered network twin operation.

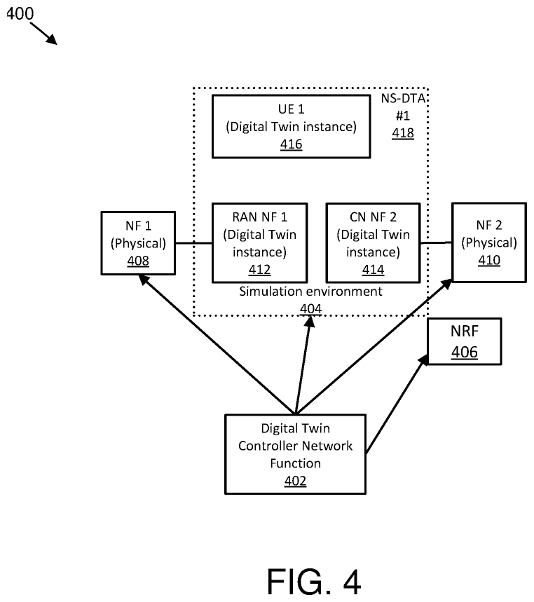

FIG. 4 is a schematic block diagram illustrating one embodiment of a system 400 in a configuration phase. The system 400 includes a digital twin controller network function 402 that configures and/or communicates with a simulation environment 404, a new radio function (“NRF”) 406 (e.g., for mapping of profiles and/or NFs to NS-DTAs and NS-DTI list), an NF 1 (e.g., physical) 408, and an NF 2 (e.g., physical) 410. Moreover, the simulation environment 404 includes a RAN NF 1 (e.g., digital twin instance) 412, a RAN NF 2 (e.g., digital twin instance) 414, a UE 1 (e.g., digital twin instance) 416, and network service (“NS”) digital twin aggregate (“DTA”) (“NS-DTA”) #1 418. It should be noted that NS-DTI may be similar to a network twin instance. Further, an NS-DTA may be similar to a network twin construct. The configuration phase may include six steps, in certain embodiments. As used herein, a configuration entity may be a network entity, an application entity, and/or an application enablement entity.

In one embodiment of a first step, there may be a network service digital twin instance (“NS-DTI”) creation by creating a replica of a network service physical twin instance (“NS-PTI”) at a corresponding network function and/or entity. For example, in edge RAN, an NS-DTI can be a twin radio network information service (“RNIS”), a radio resource control (“RRC”) function, or a distributed unit (“DU”) service and/or function instance. NS-DTI may have a unique identifier (“ID”) which is correlated with the NS-PTI. This ID may be similar to an NF ID.

In certain embodiments of a second step, a function which produces the NS-DTI (e.g., producer of the NS-PTI) sends the NS-DTI configuration to a digital twin configuration function (“DTCNF”) which stores the configurations. The DTCNF may be a RAN controller, a core network (“CN”) controller, or an edge capability. Moreover, the DTCNF may be similar to a digital twin controller function. The configuration may include: 1) an NF ID, an NF type, a network service ID and/or type, and/or an NS-DTI ID; and/or 2) configuration parameters such as a service coverage, required inputs, report configurations, expected outputs, expected consumers, algorithms used, key performance indicator (“KPI”) targets, dependencies with other NF services, and/or required signaling with other NFs.

In some embodiments of a third step, in the background, the NS-DTI is receiving from the physical twin NF (e.g., NS-PTI) the parameters which are needed to replicate the NF. Such parameters, in the case of RAN, may be the NF service configurations, the NF coverage and/or availability, NF timers, medium access control (“MAC”) scheduler information (e.g., if a digital twin (“DT”) NF is about layer 2 (“L2”) and/or MAC), MDT and/or SON parameters, and so forth.

In various embodiments of a fourth step, the DTCNF performs the matching of vertical requirements for a set of target use cases corresponding to potential customer demands (e.g., stadium, V2X, and so forth) to a list of customer profiles with certain attributes that may be derived by a SLA, generic slice template (“GST”), and/or network slice type (“NEST”). For example: 1) expected user density for different times and areas (e.g., low, medium, high load in a cell area); 2) expected physical event in a cell area for a given time; 3) critical communications and/or high density of critical services in a cell area; 4) service type with diverse and demanding requirements (e.g., ehealth); 5) mixture of services in a target area under different load circumstances; 6) different mobility scenarios (e.g., low, medium, high); and/or 7) slice SLA.

In certain embodiments of a fifth step, the DTCNF, based on requirements, creates a “vertical profile” and generates a network twin construct (e.g., NS-DTA) which is a set of twin NFs and optionally user equipments (“UEs”) for a particular vertical service (e.g., based on KPIs, service area, and so forth). This construct may have a unique ID (e.g., NS-DTA ID) to characterize the profile, and may be mapped to a set of the NS-DTI IDs of constituent instances. The list of the NS-DTI IDs and their mapping to NF IDs may be stored at a network repository function.

One example of a construct for a V2X profile may be for a target area, a set of gNBs, an AMF, an SMF, a PCF, a V2X control function (“V2XCF”), and/or an edge based V2X server (e.g., with given policies and/or configurations for V2X traffic and/or for some particular V2X applications and with given requirements (e.g., high mobility, side-link support, hybrid positioning, and so forth)). In some embodiments, the NS-DTA may include only NF and assume that a given number of dummy UEs will be simulated. In various embodiments, the NS-DTA may include the twins of the 5GS registered UE in a given area or for a given application (e.g., this may be used for UE-based simulations).

In certain embodiments of a sixth step, the DTCNF creates a simulation environment for each NS-DTA. This environment set-up may be based on vertical use case requirements, a type of environment, an expected UE density in a given area, expected load changes, a type of schedulers used, a distribution of traffic within the cell areas, and/or arrival and/or departure UE rates for a given cell area. This simulation setup may include simulation tools and a set of parameters to be used as assumptions for the simulations (e.g., assumptions book). For example: 1) channel models; 2) UE density; 3) base station (“BS”) density; 4) backhaul technologies and/or topologies; 5) access types and/or spectrum considerations; 6) schedulers; 7) distribution of UEs; 8) distribution of traffic; 9) a type of UEs and/or services; 10) RAN protocol parameterizations; and/or 11) RRC timers.

In some embodiments, the DTCNF may provide information on expected output metrics of the simulation which may be different for different consumers and may include: 1) running simulations for a different scenario and possible consumers of this scenario; 2) different metrics needed for different consumers; and/or 3) candidate consumers: NF, AF, UE, edge server, and/or application clients.

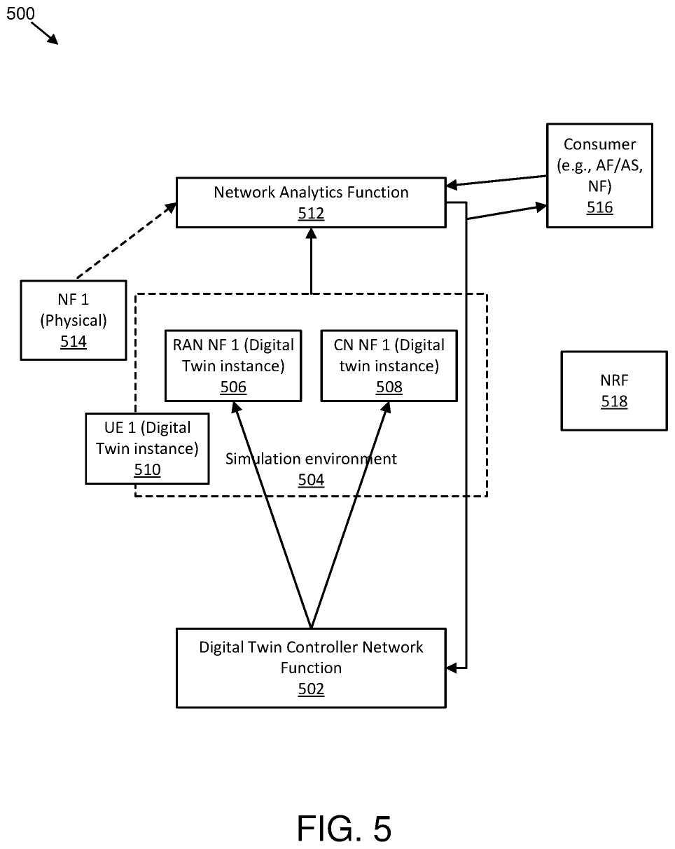

FIG. 5 is a schematic block diagram illustrating one embodiment of a system 500 in a network twin operation phase. The system 500 includes a digital twin controller function 502 that configures and/or communicates with a simulation environment 504. The simulation environment 504 includes a RAN NF 1 (e.g., digital twin instance) 506 and a CN NF 1 (e.g., digital twin instance) 508, and a UE 1 (e.g., digital twin instance) 510. The simulation environment 504 may communicate with a network analytics function 512 which may communicate with a NF 1 (e.g., physical) 514 and a consumer (e.g., AF and/or AS, NF) 516. The system 500 also includes an NRF 518. The network twin operation phase may include six steps, in certain embodiments, and may take as a pre-condition the phase configuration of the NS-DTI and/or DTAs.

In various embodiments of a first step, a third (“3^{rd}”) party customer via an AF and/or AS subscribes to a network analytics function for receiving enhanced analytics (or DT-enabled simulation outputs) for an expected service. This request may include the application ID, the service requirements, a possible event (e.g., stadium event), and a possible time of the day and geographical area. The network analytics function may be NWDAF, ADAES, or MDAS. Moreover, the network analytics function may be co-located or the same entity with the DTCNF. In certain embodiments, the AF subscribes to DTCNF directly (e.g., via a network exposure function (“NEF”)).

In certain embodiments of the first step, the consumer of the DT-enabled analytics may be the physical NF or another NF (e.g., PCF) which requests simulation outputs as inputs for performing session related decisions. In this step, the NF makes a subscription request for the DT-enabled analytics.

In some embodiments of a second step, the network analytics function matches the application request with the vertical profile (e.g., taking also into account available analytics on the expected conditions such as a load at the area and time of the request) and requests from the DTCNF to initiate the simulations for the matched NS-DTA. This request (or command and/or notification) includes the vertical profile ID or NS-DTA (e.g., if the network analytics function has a pre-configured mapping table), the time period and area of the simulations to be performed, the list of target UEs within the application or in the target area, and the reporting configuration.

In various embodiments of a third step, the DTCNF requests from the NS-DTIs within the NS-DTA to activate for a given parameterization, and the system level simulations start at the simulation environment. This may include an up to date status request and report from the NS-DTI to the corresponding physical twin NFs (e.g., NS-PTIs). The parameterization of the simulations is based on the vertical profile and the NS-DTA configuration. Also, the metric to be simulated may be different from different expected consumers. This request may also include how much data is needed to be reported or how many different what-if scenarios need to run or how many simulation (e.g., sim) snapshots need to be generated (e.g., in snapshot-based sim).

In certain embodiments of a fourth step, the simulation environment or the DTCNF, if the simulation finishes, provides the reporting to the network analytics function and includes raw data for the sim outputs.

In a first example, assuming Monte Carlo simulations (e.g., based on a configuration in phase 1), makes 10000 snapshots for a 3-cell area (e.g., cell #1, #2, #3) with 100 active UEs uniformly distributed of certain traffic type with certain channel models with inter-cell RRM #1 algorithm (e.g., coordinated multi-point transmission and/or reception (“CoMP”)), with handover (“HO”) probability X %, with av user mobility, and so forth. Based on this, extract the downlink (“DL”), uplink (“UL”), and/or sidelink (“SL”) worst case, peak, and/or mean data rates, the RAN latency, the HO failure rates, the distribution of signal to interference and noise ratio (“SINR”), cell edge vs center performance expected BS load, and so forth.

In a second example, for a UE-based dynamic simulation, initially make a drop of UEs in a target cell area, and every snapshot moves the target UEs based on the predicted mobility patterns, and extracts the SINR distribution for the target UEs, and/or QoS and/or QoE hypothetical data based on different scheduling policies. As an example, for a worst-case scenario, test the possible change of QoS profile and/or data radio bearer (“DRB”) for one or more of the sessions and how this affects per UE and per RAN performance, and also quantify the possible signaling and/or complexity overhead.

In some embodiments of a fifth step, the network analytics function, after receiving the raw data, predicts resource and/or feature needs per scenario per area. For example, the required bandwidth per application, the optimal slice RRM policies, the spectrum sharing among cells, the backhaul (“BH”) resources needed, the cloud computational resources, and/or added optimization features (e.g., QoS monitoring). Also, it may indicate possible network and/or QoS adaptations which may be pro-actively performed to avoid service downgrade (e.g., by more intelligently overprovisioning resources in high “risk” scenarios).

In various embodiments of a sixth step, the network analytics function exposes the derived analytics on the predicted service performance and/or experience and the needed network support to allow the AF and/or AS to make a service request accordingly (e.g., AF identifies the QoS requirements for the given service per area and per UE). If the reporting includes possible additional features and/or resources than the ones that the vertical has subscribed this may trigger the SLA negotiation. In this step, the derived analytics may be also provided to the consumer NF.

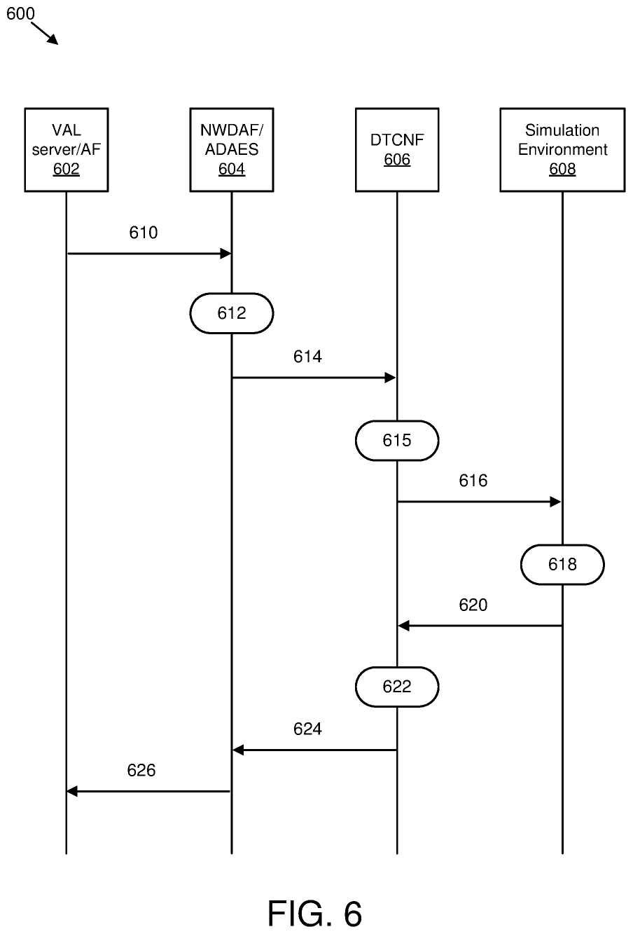

In a first embodiment, illustrated in FIG. 6, there may be a use of twining for analytics enhancements.

FIG. 6 is a schematic block diagram illustrating one embodiment of a system 600 that uses twining for analytics enhancements. The system 600 includes a vertical application layer (“VAL”) server and/or AF 602, an NWDAF and/or ADAES 604 (e.g., application data analytics function), a DTCNF 606, and a simulation environment 608 (e.g., including multiple instances of NS-DTI). Each of the communications in the system 600 may include one or more messages.

In a first communication 610, the AF 602 (or xApp) requests DT-enabled analytics from an analytics function (e.g., NWDAF, MDAS, ADAES).

The analytics function matches 612 the analytics event (e.g., using the DT-enablement flag) to a vertical scenario from a configured scenario. Based on this mapping, it binds the VAL server and/or AF-Service-ID to a vertical profile ID.

In a second communication 614, the analytics function discovers the DTCNF 606 corresponding to the target vertical profile, and sends a command to the DTCNF 606 to initiate a simulation for the vertical profile and the type of simulation (e.g., for a particular UE or for a topological area). The analytics function also sends the configuration for the reporting and provides details of the requestor entity (e.g., AF ID, VAL server ID). If the analytics function is the ADAES, this is done via a network twin API call via NEF. If the analytics function is the NWDAF, this is done via a service based interface (“SBI”) API or via common API framework (“CAPIF”) APIs. If the analytics function is an OAM service and/or mobile network service (“MnS”), this is done via management-control plane service based (“SB”) interaction. In some embodiments, the DTCNF 606 may be an AF or an SA6-defined enablement service.

The DTCNF 606 maps 615 the vertical profile #1 to the NS-DTA #1 based on the configuration of the mapping.

In a third communication 616, the DTCNF 606 requests the NS-DTIs of the NS-DTA #1 to initiate the simulations. Such request may be performed also via a gateway and/or coordination function at the simulation environment 608 (e.g., data collection coordination function (“DCCF”)).

Simulations are executed 618 by the simulation environment 608, and the outputs are stored for different metrics and types of consumers. Then, in a fourth communication 620, the NS-DTA or the respective NS-DTIs sends the raw data (e.g., which are the simulation outputs) to the DTCNF 606 (e.g., directly or via DCCF).

The DTCNF 606 may perform 622 further analytics (e.g., based on NF, UE, and/or AF data based on the analytics ID, and based on both DT data and conventional data it derives more granular analytics (or prescriptions as additional service).

In a fifth communication 624 and/or a sixth communication 626, the DTCNF 606 sends the DT-analytics outputs to the 3rd party and/or external consumer.

In a second embodiment, there may be edge RAN twining. This embodiment may cover the case if a network twin applies for a RAN element for virtual RAN deployments at an edge. The notion of edge-RAN may mean access points and RAN functions at an edge. This may be like a centralized RAN (“C-RAN”) or may be a physical RAN deployment and/or cluster.

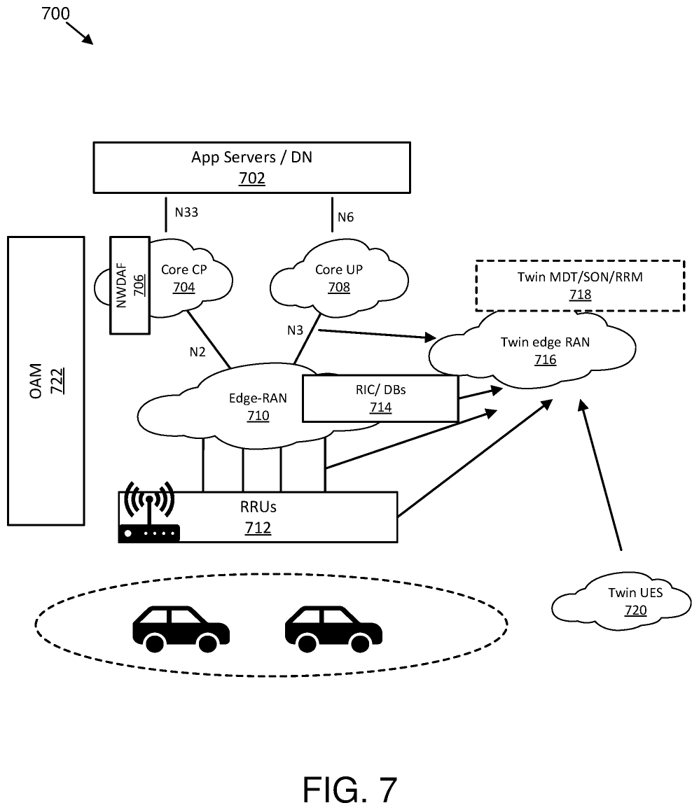

FIG. 7 is a schematic block diagram illustrating one embodiment of a system 700 for RAN twining. The system 700 includes app servers and/or DN 702, a core control plane (“CP”) 704 (which may include a NWDAF 706), a core UP 708, an edge-RAN 710, remote radio units (“RRUs”) 712, RIC and/or data bearers (“DBs”) 714, a twin edge ran 716, a twin MDT, SON, and/or RRM 718, twin UEs 720, and an OAM 722.

In the framework of FIG. 7, an NS-DTI can be a RAN element (e.g., gNB, CU, DU, and so forth) and a set of UEs within the RAN area, and other physical objects within this area. Also, an NS-DTA may be the collection of all DTIs within the RAN target area.

The consumer of the DT-based analytics service is the physical RAN NF and it may be assumed that the configuration has already been performed. The consumer RAN NF (e.g., which can be the physical RAN twin), may require a different level of DT support, so it can be either in form of raw data from simulations, predictions, or recommendations. For this, there may be possible splits between operations at the NS-DTA and NS-PTA/PTI.

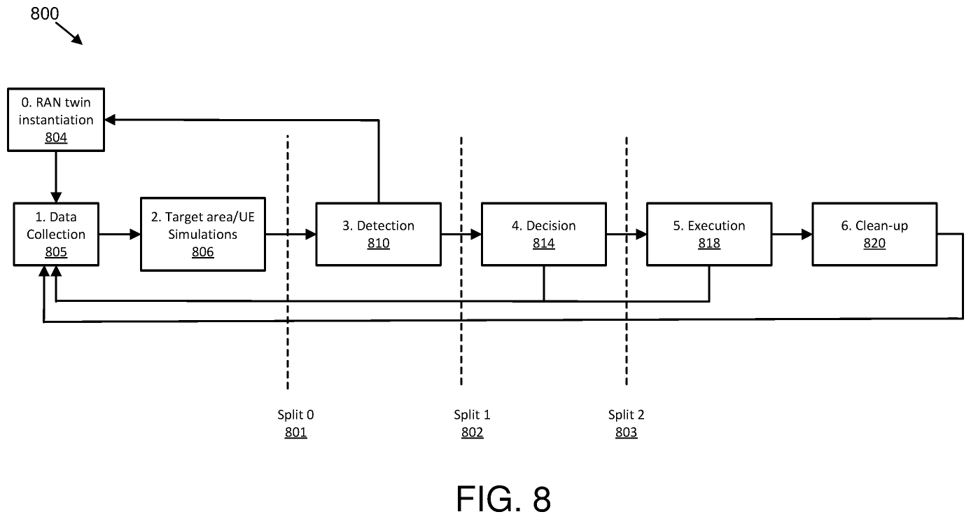

FIG. 8 is a schematic block diagram illustrating one embodiment of a system 800 with a split of DT and PT. In FIG. 8, there are three splits that may be possible between a physical twin and/or RAN and a digital twin. Split 0 801 is for the case if NS-DTA only provides evaluation results to the physical RAN twin, so the role is just diagnostic. Split 1 802 is for the case if the role of NS-DTA is to predict an event or generate a trigger. The physical twin RAN may still decide on the action to be made based on the trigger (e.g., radio change, HO, and so forth). Split 2 803 is for the case that NS-DTA also prescribes an action, and this is used as a recommendation or may be enforced at the physical twin.

In step 0 804, there is RAN twin instantiation. An NS-DTI may be a RAN element or a UE. If a UE is registered to 5GS, a RAN entity is activated, or an interface is established (e.g., if the instance is the link), then a new DTI is instantiated. Following this, the NS-DTI is mapped to a NS-DTA based on the configuration per vertical. To do the instantiation, if this is a mirror of a network element, the OAM needs to handle the DTI life cycle management (“LCM”) aspects in a similar manner as in any managed functions. If the DTI is a replica of a UE, then the DTCNF will need to create the mirror UE and place it at the edge RAN twin aggregate based on the vertical requirements. NS-DTA constructs may be assumed to be already deployed. Finally, this step may include the RAN and/or UE protocol mirroring configuration from the DTCNF. For example, to mirror the RAN protocols of UEs and RAN within a DTA. The mirroring may be only for the configuration parameters. At the next steps, the UE and/or RAN-associated parameters and context may be provided for the completion of the mirroring.

In step 1 805, there is data collection. There may be different data to be collected from a physical twin and provided to the NS-DTA and there may be different categories: 1) non-UE associated static and/or semi-static which may include a) high definition (“HD”) maps and/or static objects, b) weather conditions and/or forecast, c) zones and/or areas average load and/or performance (e.g., analytics), d) RAN protocol configurations (e.g., for the mirroring), e) BS, CU, and/or DU locations and capabilities; and/or f) GST parameters and/or list of slices per area; 2) non-UE associated dynamic which may include a) moving objects, b) RAN performance measurements, analytics (e.g., physical resource block (“PRB”) usage, and so forth), c) cell level and slice level L2 measurements, d) energy efficiency levels, e) RAN events (e.g., congestion, and so forth), and/or f) slice related parameters (e.g., PM, FM, analytics monitoring); 3) UE associated static and/or semi-static which may include UE type, RAT capabilities, vehicle plates, apps, and so forth; and/or 4) UE associated dynamic which may include UE measurements (e.g., UL and/or DL throughput, and so forth). These parameters may be the necessary inputs for the DTI and/or DTA mirroring and may enable the edge RAN twin (e.g., NS-DTA) to be up to date on the information from a RAN, a UE, and other sources.

In step 2 806 simulations may be run. In NS-DTA at the simulation environment (e.g., based on a certain trigger from the DTCNF), a simulation may be initiated. These may be mainly system level simulations and may take as input the analytics and/or outputs of the AI and/or ML algorithms for a target area of a user. Such simulations may be UE-based, dynamic, or Monte Carlo simulations based on the configurations. Also, the DTCNF may provide in advance simulation tools for the initiation of the simulations.

For a target area, a function may be needed to match all the DTIs in a DTA (e.g., vertical specific), and may calculate an expected performance via modeling all the links. In one example, based on the expected mobility of objects, the channel models, and/or the expected resource availability, a simulator may test the expected SINR within this area for a given area, and may provide a visualized SINR heatmap. One more complex type of simulations may be user-centric, since this may require the simulations to “follow” the UE. The simulations may also be link level for certain occasions (e.g., UAV to pilot link).

Step 3 810 may include detection. The detection may either happen at a mirror RAN (e.g., NS-DTA), or at a physical RAN twin based on the deployment. If the detection is at the physical twin, the simulations outputs will need to be provided from NS-DTA to NS-DTI and from NS-DTI to Physical RAN twin. The detection may be based on the simulations output: 1) a predicted and/or expected RRC message and/or radio bearer reconfiguration; 2) a predicted and/or expected Xn HO request; and/or 3) a predicted and/or expected cell load threshold crossing. Such detection may be the trigger of an action based on simulations and preset thresholds. Also, there may be externally provided detections by a 3rd party and/or upper layers (e.g., which interact with the digital twin), such as a request by the V2X service consumer (e.g., by a driver to evaluate the possibility for going to full automation), or a subscription for testing new functionalities and/or features for the service (e.g., negotiation SLA), or a notification from a CN.

Step 4 814 may include a decision. The decision is actually the outcome of the RAN function or the mirrored RAN function based on the detection. Such decision may be to perform an Xn HO, adapt intercell interference coordination (“ICIC”) methods, adapt scheduling policies, perform RB related actions, remap a flow to different radio access bearer (“RAB”), and so forth. The decision, if it comes from the DTA, needs to be provided to DTI (e.g., vBS, vUE) and then to the physical world (e.g., physical CU or DU, physical UE). This may be done via standardized interfaces, or may be proprietary.

Step 5 818 may include execution. The execution entity may be the actual entity which may apply and/or enforce the decision. This may be at the physical domain.

Step 6 820 may include clean-up. Post-execution clean-up may refer to an action of completing the change and notifying on the result. In some cases (e.g., app context transfer), the clean-up may involve the deletion of context and/or deactivation of a function and/or server at the source RAN and/or edge entity (e.g., if the UE moves to the target successfully).

A third embodiment may be an O-RAN embodiment in which: 1) a RIC has exposure to 3rd party xApp which may optimize RAN parameters; 2) a RIC can make use big data analytics and may be deployed at an edge; 3) an O-RAN digital twin controller (“O-DTC”) function (e.g., which may be similar to DTCNF) may make use of big data analytics for simulating all RAN related actions (e.g., what if scenarios); 4) an O-DTC may test performance and make sure that an O-RAN cell cluster will have guaranteed availability and/or performance; and/or 5) an O-DTC may help AI and/or ML model training and inference at an edge without needing real-time events from RAN nodes. The DT may be the source of measurements instead of the E2 nodes and UEs.

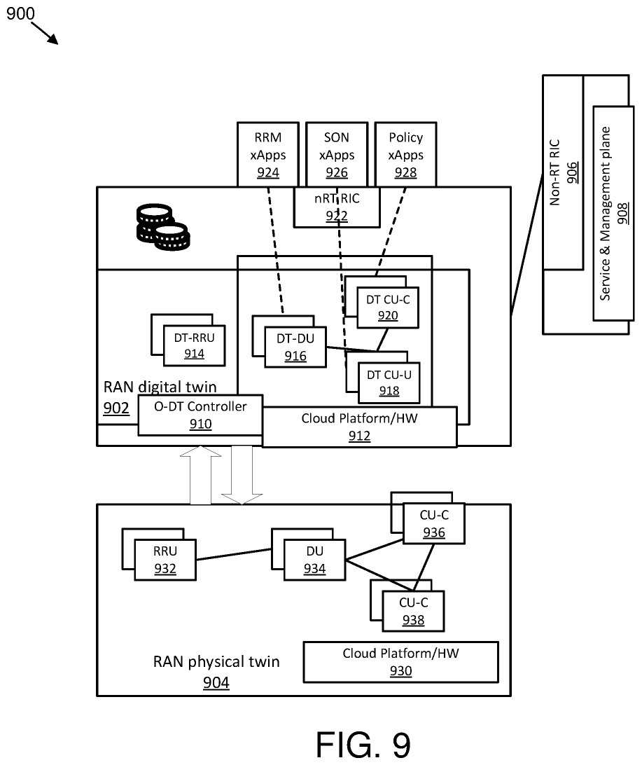

FIG. 9 is a schematic block diagram illustrating one embodiment of an O-RAN system 900. The O-RAN system 900 includes a RAN digital twin 902, and a RAN physical twin 904. The RAN digital twin 902 communicates with a non real time (“RT”) (“non-RT”, “nRT”) RIC 906 and a service & management plane 908. The RAN digital twin 902 includes an O-DT controller 910, a cloud platform and/or hardware (“HW”) 912, a DT-RRU 914, a DT-DU 916, a DT centralized unit (“CU”) user (“U”) (“CU-U”) 918, a DT CU consumer (“C”) CU-C 920, and an nRT RIC 922 which communicate with RRM xApps 924, SON xApps 926, and policy xApps 928. Further, the RAN physical twin 904 includes an RRU 932, a DU 934, a CU-C 936, a CU-C 938, and a cloud platform and/or HW 930.

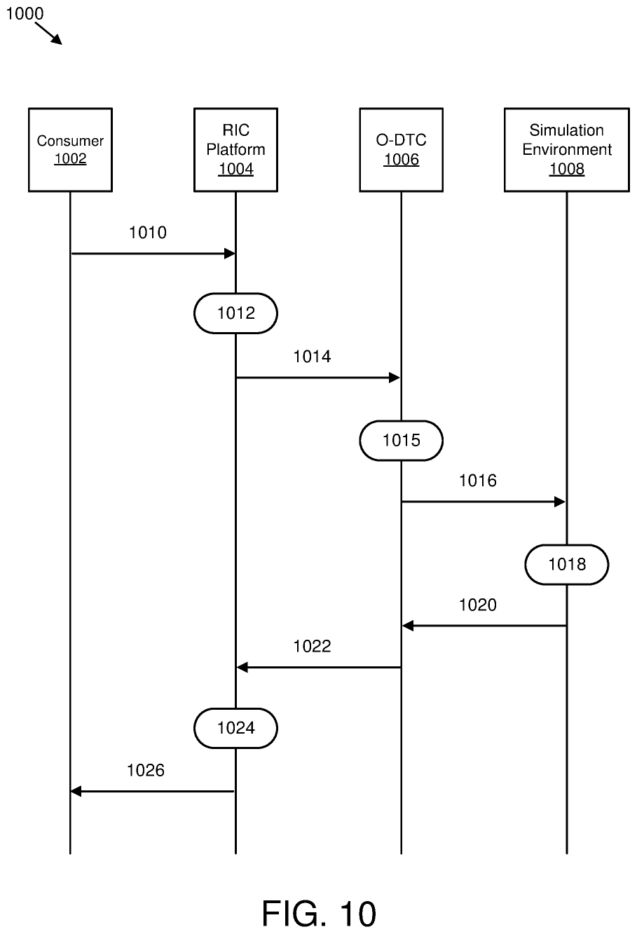

FIG. 10 is a schematic block diagram illustrating one embodiment of a system 1000 implementing the third embodiment. The system 1000 includes a consumer 1002 (e.g., service management and orchestration (“SMO”), xApp), a RIC platform 1004 (e.g., AI and/or ML support, NIB, an O-DTC 1006, and a simulation environment 1008 (e.g., including multiple instances of NS-DTI (e.g., E2 nodes, UEs)). Each of the communications in the system 1000 may include one or more messages.

In a first communication 1010, the SMO (or xApp) requests DT-enabled support for a certain application type.

The RIC platform 1004 maps 1012 the request to a use case (e.g., from the O-RAN use cases).

In a second communication 1014, the RIC platform 1004 sends a command to the O-DTC 1006 to initiate a simulation for the O-RAN use case and the type of simulation (e.g., for a particular UE or for an area). It also sends the configuration for the reporting and provides details of the requestor entity (e.g., SMO).

The O-DTC 1006 maps 1015 the use case to the NS-DTA #1 based on the configuration of the mapping.

In a third communication 1016, the O-DTC 1006 requests the NS-DTIs of the NS-DTA #1 to initiate the simulations.

The simulation environment 1008 executes 1018 the simulations, and the outputs are stored for different metrics and types of consumers. Then, in a fourth communication 1020 and a fifth communication 1022, the NS-DTA or the respective NS-DTIs send the raw data (e.g., which are the simulation outputs) to the RIC platform 1004.

The RIC platform 1004 may perform 1024 further analytics (e.g., using R-NIB or UE-NIB services and based on both DT data and RIC DB data it performs AI-assisted RRM and/or SON optimization).

In a sixth communication 1026, the RIC platform 1004 sends the AI-assisted RRM and/or SON optimization output to the consumer 1002. In certain embodiments, if the consumer 1002 of the RIC platform 1004 is SMO, it may send the DT raw data to allow for further non-RT optimization at non-RT RIC.

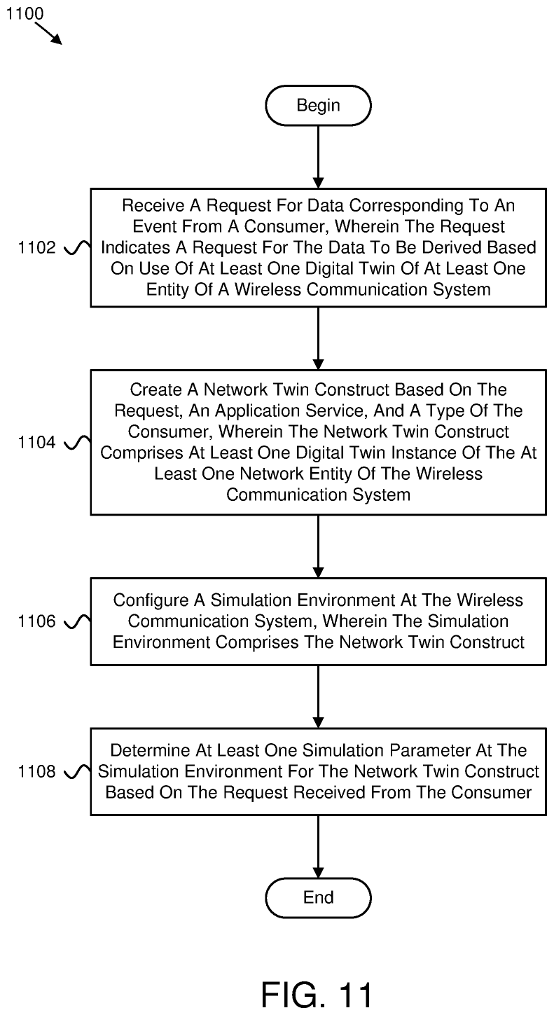

FIG. 11 is a flow chart diagram illustrating one embodiment of a method 1100 for determining simulation information for a network twin. In some embodiments, the method 1100 is performed by an apparatus, such as the network unit 104. In certain embodiments, the method 1100 may be performed by a processor executing program code, for example, a microcontroller, a microprocessor, a CPU, a GPU, an auxiliary processing unit, a FPGA, or the like.

In various embodiments, the method 1100 includes receiving 1102, at a configuration entity, a request for data corresponding to an event from a consumer. An event from a consumer may be applicable to an application driven event from an application entity (e.g., a server, a client, an enablement entity or a combination) and/or a network driven event from a network function, and/or a management driven event from a management domain or function or service. An application driven event may be in form of a new or modified service requirement from a 3rd party application. Further, a network driven event can be in form of a certain configuration or situation or parameterization of a network entity (e.g., different QoS offering, load situation, NF availability, connection distribution may comprise one or more events). Moreover, a management driven event may be in form of a management service output (e.g., a slice lifecycle configuration or change, a managed network entity availability change). Data may be, for example, one or more of simulation data, notifications, alerts, trained AI/ML model data, and so forth. The request indicates a request for the data to be derived based on use of at least one digital twin of at least one entity of a wireless communication system. This entity may be a network unit, a remote unit, a management entity, an O-RAN node, a RIC, a network protocol, a transport and/or backhaul node, an AF, a UE modem, and so forth. In some embodiments, the method 1100 includes creating 1104 a network twin construct based on the request, an application service, and a type of the consumer. A type of consumer may refer to the domain it belongs. The type may be network based consumer, a trust 3rd party application entity, a management service or function or domain, a vertical UE, an application of a UE, or a combination thereof. The network twin construct includes at least one digital twin instance of the at least one network entity of the wireless communication system. It should be noted that a network twin construct may be defined as a customized aggregate of a plurality of digital twin instances of at least one entity of a wireless communication system. In certain embodiments, the method 1100 optionally includes configuring 1106 a simulation environment at the wireless communication system. The simulation environment includes the network twin construct. In some embodiments, a simulation environment includes a simulation platform, configuration parameters and simulation tools for providing simulations. In various embodiments, the method 1100 includes determining 1108 at least one simulation parameter at the simulation environment for the network twin construct based on the request received from the consumer. In some embodiments, a simulation parameter includes configuration parameters for the simulation setup at the simulation environment. Such configuration may be, for example, the distribution of devices within an area, the active UE sessions, the network conditions, the channel models, the target KPI for the service, slice SLA and slice instance configurations, protocol configurations for the network elements (e.g., RRC configuration, etc.).

In certain embodiments, the request comprises a requirement for exposure of the data corresponding to the event, an event type, an application service profile, a time of validity for the request, a frequency of data reporting, an area of interest for the request, or some combination thereof. An application service profile may refer to the type of application service (e.g., eMBB, V2X, IIOT, URLLC) and/or the profile information of a specific application service (e.g., capabilities, KPIs, battery status, trusted or untrusted, permissions, etc.). In some embodiments, the configuration entity comprises a digital twin configuration network, a digital twin controller function, a management function, an application function, or a combination thereof. In various embodiments, the consumer comprises an application data analytics enablement service, a network data analytics function, a management domain analytics service, an application server, an application function, a network function, or some combination thereof.

In one embodiment, the method 1100 further comprises mapping the network twin construct to a list of network twin instances, a list of network twin configurations, or a combination thereof. In certain embodiments, the method 1100 further comprises mapping the network twin construct to a vertical service, a vertical device, a network slice, or a combination thereof. In some embodiments, the wireless communication system comprises a virtualized RAN system.

In various embodiments, the network twin construct comprises at least one digital twin of at least one virtualized RAN function, protocol, or a combination thereof. In one embodiment, the data corresponding to the event comprise data of RAN performance, a user equipment (UE) performance, a group of UEs performance, or some combination thereof. In certain embodiments, the configuration entity, the network twin construct, the network analytics function, or some combination thereof reside at an edge platform, a RIC platform, or a combination thereof.

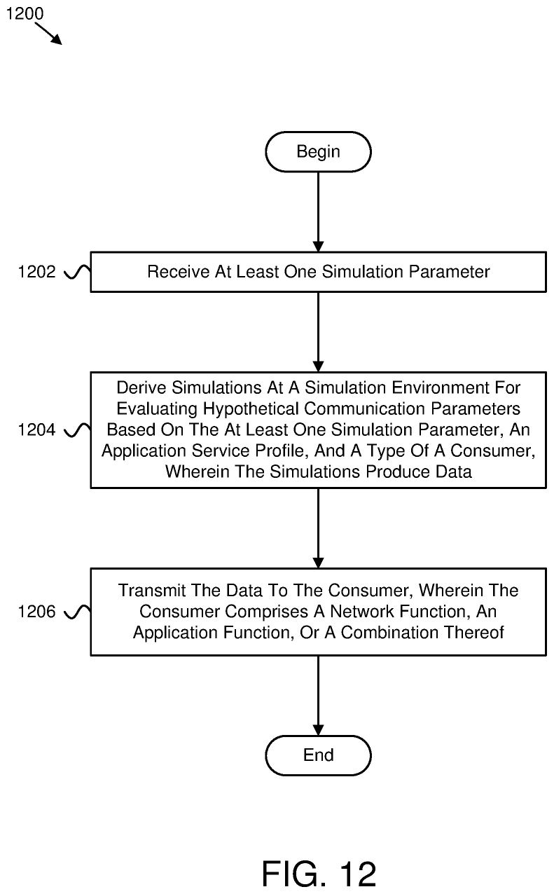

FIG. 12 is a flow chart diagram illustrating another embodiment of a method 1200 for determining simulation information for a network twin. In some embodiments, the method 1200 is performed by an apparatus, such as the network unit 104. In certain embodiments, the method 1200 may be performed by a processor executing program code, for example, a microcontroller, a microprocessor, a CPU, a GPU, an auxiliary processing unit, a FPGA, or the like

In various embodiments, the method 1200 includes receiving 1202, at a network twin construct, at least one simulation parameter. In some embodiments, the method 1200 includes deriving 1204 simulations at a simulation environment for evaluating hypothetical communication parameters based on the at least one simulation parameter, an application service profile, and a type of a consumer. It should be noted that hypothetical communication parameters are communication parameters for one or more cell areas and/or one or more target UEs corresponding to hypothetical events. Such hypothetical events may be different network load situations, resource availability, resource conditions, different time of the day, UE connection density, and distribution of traffic within a target area, etc. The simulations produce data. In certain embodiments, the method 1200 includes transmitting 1206 the data to the consumer. The consumer includes a network function, an application function, or a combination thereof.

In certain embodiments, the method 1200 further comprises deriving analytics based on the performed simulations, wherein the analytics comprise predictions, prescriptions, or a combination thereof related to adaptation of network parameters, edge parameters, application parameters, or a combination thereof. A network parameter may be a QoS parameter or profile, a NF parameter, a management service output, a resource, a traffic steering decision or recommendation, a slice adaptation or slice modification decision or recommendation, and so forth. Moreover, an edge parameter may be an edge network performance parameter, an edge platform load parameter, an edge server performance or load or availability parameter. Further, an application parameter may be a new or modified application service performance related parameter or application QoS parameter (e.g. latency, throughput, reliability), an service operation parameter (e.g., mode of communication, level of automation, group configuration). In some embodiments, the method 1200 further comprises transmitting the derived analytics to the consumer, wherein the derived analytics are derived based on the use of the digital twins at the wireless communication system.

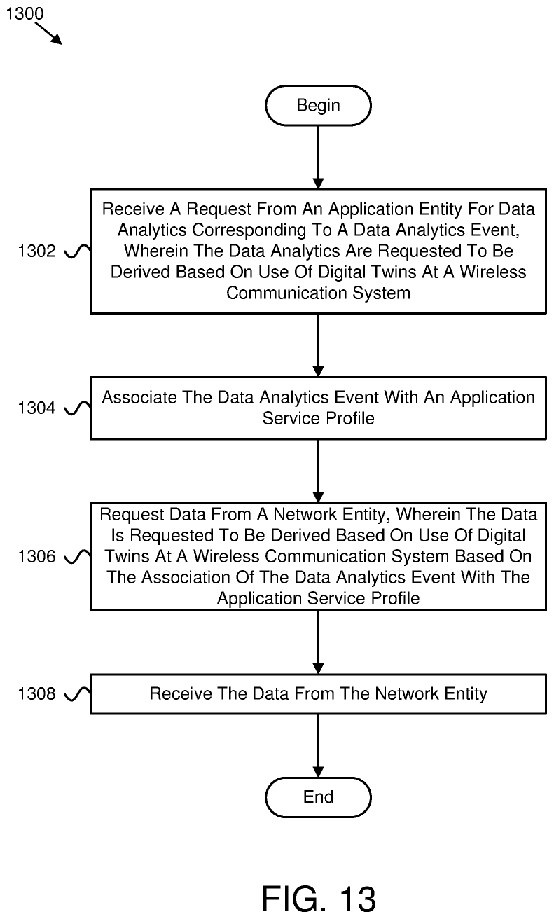

FIG. 13 is a flow chart diagram illustrating a further embodiment of a method 1300 for determining simulation information for a network twin. In some embodiments, the method 1300 is performed by an apparatus, such as the network unit 104. In certain embodiments, the method 1300 may be performed by a processor executing program code, for example, a microcontroller, a microprocessor, a CPU, a GPU, an auxiliary processing unit, a FPGA, or the like.

In various embodiments, the method 1300 includes receiving 1302, at a network analytics function, a request from an application entity for a data analytics corresponding to a data analytics event. The data analytics are requested to be derived based on use of digital twins at a wireless communication system. An application entity may be an application function, an application server, an application client, or an application enablement entity. In some embodiments, the method 1300 includes associating 1304 the data analytics event with an application service profile. In certain embodiments, the method 1300 includes requesting 1306 data from a network entity based on the association of the data analytics event with the application service profile. The data is requested to be derived based on use of digital twins at a wireless communication system. In various embodiments, the method 1300 includes receiving 1308 the data from the network entity.

In certain embodiments, the network configuration entity comprises a digital twin configuration network function, a digital twin controller function, a management function, or a combination thereof. In some embodiments, the network analytics function comprises an application data analytics enablement service, a network data analytics function, a management domain analytics service, a radio access network (RAN) intelligent controller (RIC) platform function, or some combination thereof.

In one embodiment, a method of a configuration entity comprises: receiving a request for data corresponding to an event from a consumer, wherein the request indicates a request for the data to be derived based on use of at least one digital twin of at least one network entity of a wireless communication system; creating a network twin construct based on the request, an application service, and a type of the consumer, wherein the network twin construct comprises at least one digital twin instance of the at least one network entity of the wireless communication system; configuring a simulation environment at the wireless communication system, wherein the simulation environment comprises the network twin construct; and determining at least one simulation parameter at the simulation environment for the network twin construct based on the request received from the consumer.

In certain embodiments, the request comprises a requirement for exposure of the data corresponding to the event, an event type, an application profile, a time of validity for the request, a frequency of data reporting, an area of interest for the request, or some combination thereof.

In some embodiments, the configuration entity comprises a digital twin configuration network, an application function, a digital twin controller function, a management function, or a combination thereof.

In various embodiments, the consumer comprises an application data analytics enablement service, a network data analytics function, a management domain analytics service, an application server, an application function, a network function, or some combination thereof.

In one embodiment, the method further comprises mapping the network twin construct to a list of network twin instances, a list of network twin configurations, or a combination thereof.

In certain embodiments, the method further comprises mapping the network twin construct to a vertical service, a vertical device, a network slice, or a combination thereof.

In some embodiments, the wireless communication system comprises a virtualized RAN system.

In various embodiments, the network twin construct comprises at least one digital twin of at least one virtualized RAN function, protocol, or a combination thereof.

In one embodiment, the data corresponding to the event comprise data of RAN performance, a user equipment (UE) performance, a group of UEs performance, or some combination thereof.

In certain embodiments, the configuration entity, the network twin construct, the network analytics function, or some combination thereof reside at an edge platform, a RIC platform, or a combination thereof.

In one embodiment, an apparatus comprises a configuration entity. The apparatus further comprises: a receiver that receives a request for data corresponding to an event from a consumer, wherein the request indicates a request for the data to be derived based on use of at least one digital twin of at least one network entity of a wireless communication system; and a processor that: creates a network twin construct based on the request, an application service, and a type of the consumer, wherein the network twin construct comprises at least one digital twin instance of the at least one network entity of the wireless communication system; configures a simulation environment at the wireless communication system, wherein the simulation environment comprises the network twin construct; and determines at least one simulation parameter at the simulation environment for the network twin construct based on the request received from the consumer.

In certain embodiments, the request comprises a requirement for exposure of the data corresponding to the event, an event type, an application profile, a time of validity for the request, a frequency of data reporting, an area of interest for the request, or some combination thereof.

In some embodiments, the configuration entity comprises a digital twin configuration network, an application function, a digital twin controller function, a management function, or a combination thereof.

In various embodiments, the consumer comprises an application data analytics enablement service, a network data analytics function, a management domain analytics service, an application server, an application function, a network function, or some combination thereof.

In one embodiment, the processor maps the network twin construct to a list of network twin instances, a list of network twin configurations, or a combination thereof.

In certain embodiments, the processor maps the network twin construct to a vertical service, a vertical device, a network slice, or a combination thereof.

In some embodiments, the wireless communication system comprises a virtualized RAN system.

In various embodiments, the network twin construct comprises at least one digital twin of at least one virtualized RAN function, protocol, or a combination thereof.

In one embodiment, the data corresponding to the event comprise data of RAN performance, a user equipment (UE) performance, a group of UEs performance, or some combination thereof.

In certain embodiments, the configuration entity, the network twin construct, the network analytics function, or some combination thereof reside at an edge platform, a RIC platform, or a combination thereof.

In one embodiment, a method of a network twin construct comprises: receiving at least one simulation parameter; deriving simulations at a simulation environment for combining hypothetical communication parameters based on the at least one simulation parameter, an application service, and a type of a consumer, wherein the simulations produce data; and transmitting the data to the consumer, wherein the consumer comprises a network function, an application function, or a combination thereof.

In certain embodiments, the method further comprises deriving analytics based on the performed simulations, wherein the analytics comprise predictions, prescriptions, or a combination thereof related to adaptation of network parameters, edge parameters, application parameters, or a combination thereof.

In some embodiments, the method further comprises transmitting the derived analytics to the consumer, wherein the derived analytics are derived based on the use of the network twins at the wireless communication system.

In one embodiment, an apparatus comprises a network twin construct. The apparatus further comprises: a receiver that receives at least one simulation parameter; a processor that derives simulations at a simulation environment for combining hypothetical communication parameters based on the at least one simulation parameter, an application service, and a type of a consumer, wherein the simulations produce data; and a transmitter that transmits the data to the consumer, wherein the consumer comprises a network function, an application function, or a combination thereof.

In certain embodiments, the processor derives analytics based on the performed simulations, and the analytics comprise predictions, prescriptions, or a combination thereof related to adaptation of network parameters, edge parameters, application parameters, or a combination thereof.

In some embodiments, the transmitter transmits the derived analytics to the consumer, and the derived analytics are derived based on the use of the network twins at the wireless communication system.

In one embodiment, a method of a network analytics function comprises: receiving a request from an application function for a digital twin enabled data analytics event; associating the digital twin enabled data analytics event with an application service profile; requesting data from a network entity, wherein the simulation data is requested to be derived based on use of network twins at a wireless communication system; and receiving the data from the network entity.

In certain embodiments, the network configuration entity comprises a digital twin configuration network function, a digital twin controller function, a management function, or a combination thereof.

In some embodiments, the network analytics function comprises an application data analytics enablement service, a network data analytics function, a management domain analytics service, a radio access network (RAN) intelligent controller (RIC) platform function, or some combination thereof.

In one embodiment, an apparatus comprises a network analytics function. The apparatus further comprises: a receiver that receives a request from an application function for a digital twin enabled data analytics event; a processor that associates the digital twin enabled data analytics event with an application service profile; and a transmitter that requests data from a network entity, wherein the simulation data is requested to be derived based on use of network twins at a wireless communication system, wherein the receiver receives the data from the network entity.

In certain embodiments, the network configuration entity comprises a digital twin configuration network function, a digital twin controller function, a management function.

In some embodiments, the network analytics function comprises an application data analytics enablement service, a network data analytics function, a management domain analytics service, a radio access network (RAN) intelligent controller (RIC) platform function, or some combination thereof.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. An apparatus for performing a network function, the apparatus comprising:
at least one memory; and
at least one processor coupled with the at least one memory and configured to cause the apparatus to:
receive a request for data corresponding to an event from a consumer, wherein the request indicates a request for the data to be derived based on use of at least one digital twin of at least one entity of a wireless communication system;
create a network twin construct based on the request, an application service, and a type of the consumer, wherein the network twin construct comprises at least one digital twin instance of at least one network entity of the wireless communication system; and
determine at least one simulation parameter at a simulation environment for the network twin construct based on the request received from the consumer.

2. The apparatus of claim 1, wherein the request comprises a requirement for exposure of the data corresponding to the event, an event type, an application service profile, a time of validity for the request, a frequency of data reporting, an area of interest for the request, or some a combination thereof.

3. The apparatus of claim 1, further comprising a digital twin configuration network, an application function, a digital twin controller function, a management function, or a combination thereof.

4. The apparatus of claim 1, wherein the consumer comprises an application data analytics enablement service, a network data analytics function, a management domain analytics service, an application server, an application function, a network function, or some a combination thereof.

5. The apparatus of claim 1, wherein the at least one processor is configured to cause the apparatus to map the network twin construct to a list of network twin instances, a list of network twin configurations, or a combination thereof.

6. The apparatus of claim 1, wherein the at least one processor is configured to cause the apparatus to map the network twin construct to a vertical service, a vertical device, a network slice, or a combination thereof.

7. The apparatus of claim 1, wherein the at least one processor is configured to cause the apparatus to configure a simulation environment at the wireless communication system, wherein the simulation environment comprises the network twin construct.

8. The apparatus of claim 1, wherein the network twin construct comprises at least one digital twin of at least one virtualized RAN function, protocol, or a combination thereof.

9. The apparatus of claim 1, wherein the data corresponding to the event comprise data of RAN performance, a user equipment (UE) performance, a group of UEs performance, or a combination thereof.

10. The apparatus of claim 1, wherein the apparatus, the network twin construct, a network analytics function, or a combination thereof reside at an edge platform, a RAN intelligent controller (RIC), or a combination thereof.

11. A method of performing a network function, the method comprising:
receiving at least one simulation parameter;
deriving simulations at a simulation environment for evaluating hypothetical communication parameters based on the at least one simulation parameter, an application service profile, and a type of a consumer, wherein the simulations produce data; and
transmitting the data to the consumer, wherein the consumer comprises a network function, an application function, or a combination thereof.

12. The method of claim 11, further comprising deriving analytics based on performed simulations, wherein the analytics comprise predictions, prescriptions, or a combination thereof related to adaptation of network parameters, edge parameters, application parameters, or a combination thereof.

13. The method of claim 12, further comprising transmitting the derived analytics to the consumer, wherein the derived analytics are derived based on use of digital twins at a wireless communication system.

14. An apparatus for performing a network function, the apparatus comprising:
at least one memory; and
at least one processor coupled with the at least one memory and configured to cause the apparatus to:
receive a request from an application entity for data analytics corresponding to a data analytics event, wherein the data analytics are requested to be derived based on use of digital twins at a wireless communication system;
associate the data analytics event with an application service profile; and
request data from a network entity based on the association of the data analytics event with the application service profile, wherein the data is requested to be derived based on use of digital twins at a wireless communication system, wherein the receiver receives the data from the network entity.

15. The apparatus of claim 14, further comprising a digital twin configuration function, a digital twin controller function, a management function, or a combination thereof; and a network analytics function comprises an application data analytics enablement service, a network data analytics function, a management domain analytics service, a radio access network (RAN) intelligent controller (RIC) platform function, or a combination thereof.

16. A method of performing a network function, the method comprising:
receiving a request for data corresponding to an event from a consumer, wherein the request indicates a request for the data to be derived based on use of at least one digital twin of at least one entity of a wireless communication system;
creating a network twin construct based on the request, an application service, and a type of the consumer, wherein the network twin construct comprises at least one digital twin instance of at least one network entity of the wireless communication system; and
determining at least one simulation parameter at a simulation environment for the network twin construct based on the request received from the consumer.

17. The method of claim 16, wherein the request comprises a requirement for exposure of the data corresponding to the event, an event type, an application service profile, a time of validity for the request, a frequency of data reporting, an area of interest for the request, or a combination thereof.

18. The method of claim 16, wherein the network function is performed by a digital twin configuration network, an application function, a digital twin controller function, a management function, or a combination thereof.

19. The method of claim 16, wherein the consumer comprises an application data analytics enablement service, a network data analytics function, a management domain analytics service, an application server, an application function, a network function, or a combination thereof.

20. The method of claim 16, further comprising mapping the network twin construct to a list of network twin instances, a list of network twin configurations, or a combination thereof.
